(19) United States
(12) Patent Application Publication
(10) Pub. No.: US 2022/0404428 A1
(43) Pub. Date: Dec. 22, 2022

(54) MANAGEMENT SYSTEM, MANAGEMENT METHOD, SERVER DEVICE, STORAGE MEDIUM, BATTERY INFORMATION PROVIDING SYSTEM, AND BATTERY INFORMATION PROVIDING METHOD

(71) Applicant: HONDA MOTOR CO., LTD., Tokyo (JP)

(72) Inventors: Akira KATO, Wako-shi (JP); Keiichi ARAI, Wako-shi (JP); Koichi TSUNO, Wako-shi (JP); Yasuhiro NAKADA, Wako-shi (JP); Tatsuya JINNO, Wako-shi (JP); Takumi SHIIYAMA, Wako-shi (JP); Ryuichi KIMATA, Tokyo (JP)

(21) Appl. No.: 17/894,507

(22) Filed: Aug. 24, 2022

Related U.S. Application Data
(63) Continuation of application No. PCT/JP2021/009207, filed on Mar. 9, 2021.

(30) Foreign Application Priority Data
Mar. 27, 2020 (JP) 2020-057886
Mar. 27, 2020 (JP) 2020-057895

(51) Int. Cl. G01R 31/392; G01R 31/396; B60L 53/30

(52) U.S. Cl. CPC G01R 31/392; G01R 31/396; B60L 53/305

(57) ABSTRACT

The present invention provides a management system for managing a battery mounted on a vehicle, comprising: an acquisition unit configured to acquire rank information indicating a product rank set by a user as a reuse destination of the battery; and a notification unit configured to notify the user of restriction item information indicating an item for restricting a function of the vehicle such that a deterioration state of the battery at a predetermined time satisfies a request state of the product rank, based on the rank information acquired by the acquisition unit.

### CROSS-REFERENCE TO RELATED APPLICATION(S)

This application is a continuation of International Patent Application No. PCT/JP2021/009207 filed on Mar. 9, 2021, which claims priority to and the benefits of Japanese Patent Application No. 2020-057886 filed on Mar. 27, 2020, and Japanese Patent Application No. 2020-057895 filed on Mar. 27, 2020, the entire disclosures of which are incorporated herein by reference.

### BACKGROUND OF THE INVENTION

### Field of the Invention

The present invention relates to a management system, a management method, a server device, and a storage medium for managing a battery, a battery information providing system, and a battery information providing method.

### Description of the Related Art

Japanese Patent Laid-Open No. 2019-160395 discloses a control device that sets a degradation target value of a secondary battery (battery) after a target period has elapsed, and controls charging and discharging of the secondary battery by limiting a state of charge (SOC) of the secondary battery to a predetermined range to reach the degradation target value. Specifically, the control device limits the upper limit value of the SOC to a range of 75% to 85% and limits the lower limit value of the SOC to a range of 30% to 40% when the secondary battery is charged.

Only controlling charging and discharging of the battery as disclosed in Japanese Patent Laid-Open No. 2019-160395 is insufficient to reduce deterioration of the battery.

### SUMMARY OF THE INVENTION

The present invention provides, for example, an advantageous technique for managing deterioration of a battery mounted on a vehicle.

According to the present invention, there is provided a management system for managing a battery mounted on a vehicle, comprising: an acquisition unit configured to acquire rank information indicating a product rank set by a user as a reuse destination of the battery; and a notification unit configured to notify the user of restriction item information indicating an item for restricting a function of the vehicle such that a deterioration state of the battery at a predetermined time satisfies a request state of the product rank, based on the rank information acquired by the acquisition unit.

Further features of the present invention will become apparent from the following description of exemplary embodiments (with reference to the attached drawings).

### BRIEF DESCRIPTION OF THE DRAWINGS

FIG. 1 is a block diagram illustrating a configuration example of a management system.

FIG. 2 is a flowchart illustrating management processing.

FIG. 3 is a diagram illustrating an example of an input screen of a scheduled sale timing.

FIG. 4 is a diagram illustrating an example of a screen for notifying of each product rank and a predicted transaction price.

FIG. 5 is a diagram for illustrating processing of determining a restriction item of a function of a vehicle.

FIG. 6 is a diagram illustrating an example of a screen for displaying recommended settings for various functions of the vehicle.

FIG. 7 is a block diagram illustrating a configuration of a battery information providing system.

FIG. 8 is a block diagram illustrating a configuration of the battery.

FIG. 9 is a block diagram illustrating a configuration of the server.

FIG. 10 is a diagram illustrating a configuration of an information processing apparatus.

FIG. 11 is a diagram for illustrating a flow of processing in a battery information providing system.

FIG. 12 is a diagram schematically illustrating a model for predicting a future life of the battery.

### DESCRIPTION OF THE EMBODIMENTS

Hereinafter, embodiments will be described in detail with reference to the attached drawings. Note, the following embodiments are not intended to limit the scope of the claimed invention, and limitation is not made to an invention that requires a combination of all features described in the embodiments. Two or more of the multiple features described in the embodiments may be combined as appropriate. Furthermore, the same reference numerals are given to the same or similar configurations, and redundant description thereof is omitted.

### First Embodiment

Japanese Patent Laid-Open No. 2019-160395 discloses a control device that sets a degradation target value of a secondary battery (battery) after a target period has elapsed, and controls charging and discharging of the secondary battery by limiting a state of charge (SOC) of the secondary battery to a predetermined range to reach the degradation target value. Specifically, the control device limits the upper limit value of the SOC to a range of 75% to 85% and limits the lower limit value of the SOC to a range of 30% to 40% when the secondary battery is charged. However, only controlling charging and discharging of the battery as disclosed in Japanese Patent Laid-Open No. 2019-160395 is insufficient to reduce deterioration of the battery.

Therefore, an object of the present embodiment is to provide an advantageous technique for managing deterioration of a battery mounted on a vehicle.

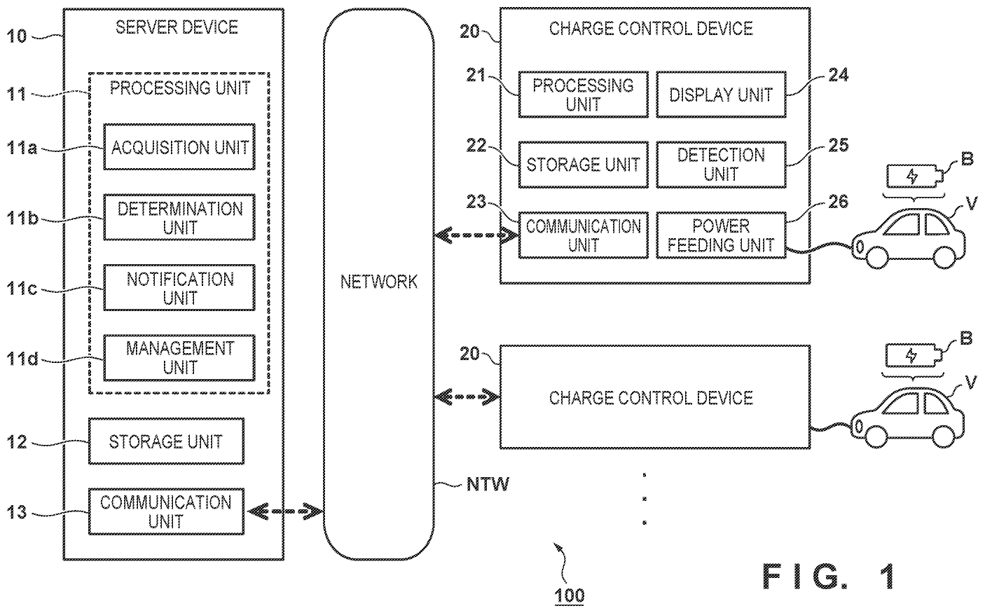

FIG. 1 is a block diagram illustrating a configuration example of a management system 100 of the present embodiment. The management system 100 of the present embodiment is a system that manages a battery B mounted on a vehicle V, and includes a server device 10 and a charge control device 20 communicatively connected to each other via a network NTW. The charge control device 20 is a facility for controlling charging of the battery B mounted on the vehicle V. For example, the charge control device 20 can be lent by an operator of the management system 100 and provided in a house for home use. Here, FIG. 1 illustrates the configuration including the plurality of charge control devices 20, but the configuration may include only one charge control device 20. In addition, the charge control device 20 is not limited to the charging of the battery B, and may control the discharging of the battery B.

First, a configuration example of the server device 10 will be described. The server device 10 includes, for example, a computer, and can include a processing unit 11, a storage unit 12 (database), and a communication unit 13. The processing unit 11 includes a processor represented by the CPU, a storage device such as a semiconductor memory or the like, an interface with an external device, and the like. The storage unit 12 stores a program to be executed by the processor, data to be used for processing by the processor, and the like. The processing unit 11 can read the program stored in the storage unit 12 to the storage device such as a memory and execute the program. In the case of the present embodiment, the storage unit 12 stores a program (management program) for managing the battery B mounted on the vehicle V, and the processing unit 11 can read the management program stored in the storage unit 12 into a storage device such as a memory and execute the management program. Furthermore, the communication unit 13 is a unit for communicating with each of the charge control devices 20 via the network NTW.

Furthermore, the processing unit 11 of the present embodiment can be provided with an acquisition unit 11a, a determination unit 11b, a notification unit 11c, and a management unit 11d. The acquisition unit 11a acquires various types of information items such as rank information indicating a product rank set (selected) by the user as a reuse destination of the battery B from the user (charge control device 20). The determination unit 11b determines a restriction item of the function of the vehicle V for reducing the deterioration of the battery B. The notification unit 11c notifies the user (charge control device 20) of various types of information items such as restriction item information indicating the restriction item of the function of vehicle V determined as the restricted target by determination unit 11b. The management unit 11d manages information such as information indicating the location and deterioration state of the battery B transmitted from the plurality of charge control devices 20.

Next, a configuration example of the charge control device 20 will be described. In the example illustrated in FIG. 1, the configuration of one charge control device 20 among the plurality of charge control devices 20 is illustrated, but other charge control devices 20 may have a similar configuration. The charge control device 20 of the present embodiment can include, for example, a processing unit 21, a storage unit 22, a communication unit 23, a display unit 24, a detection unit 25, and a power feeding unit 26. The processing unit 21 includes a processor represented by a CPU, a storage device such as a semiconductor memory, an interface with an external device, and the like, and has a function as a power control unit that controls charging of the battery B of the vehicle V by the power feeding unit 26. The storage unit 22 stores a program, data, and the like for controlling charging of the battery B, and the processing unit 21 can read the program stored in the storage unit 22 to a storage device such as a memory and execute the program. Furthermore, the communication unit 23 is a unit for communicating with the server device 10 via the network NTW.

The display unit 24 may include a display that displays information acquired from the server device 10. In the case of the present embodiment, the display unit 24 includes, for example, a touch panel liquid crystal display (LCD) or the like, and has a function as an input unit that receives an instruction from the user in addition to a function of displaying information (image). Furthermore, in the present embodiment, the display unit 24 (display) is provided in the charge control device 20, but it is not limited thereto, and may be a display provided in the vehicle V such as a car navigation system, a display of a personal computer provided in a residence, a display of an information terminal (smartphone) owned by a user, or the like.

The detection unit 25 detects a deterioration state (deterioration degree) of the battery B. For example, the detection unit 25 detects a state of health (SOH) represented by a ratio of a full charge capacity (Ah) at the time of deterioration to an initial full charge capacity (Ah)×100 as the deterioration state of the battery B, but in addition to this, may detect a state of charge (SOC) represented by a ratio of a remaining capacity (Ah) to a full charge capacity (Ah)×100. Furthermore, the power feeding unit 26 supplies power to the vehicle V (battery B) under the control of the processing unit 21. For example, the power feeding unit 26 may include an AC/DC converter that converts power (AC voltage) from a power grid into a DC voltage, a DC/DC converter that adjusts the voltage of power (DC voltage) to be supplied to the battery B, and the like.

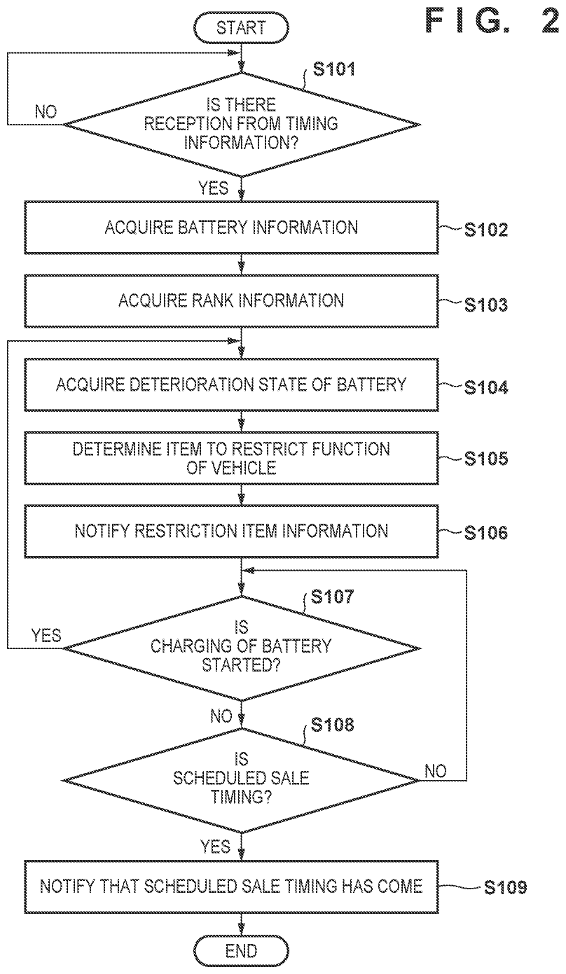

FIG. 2 is a flowchart illustrating management processing of managing the battery B. The flowchart illustrated in FIG. 2 can be performed by the processing unit 11 of the server device 10 when the management program is executed. The flowchart of the management processing illustrated in FIG. 2 can be individually executed for the battery B (that is, each of the plurality of batteries) mounted on each of the plurality of vehicles V.

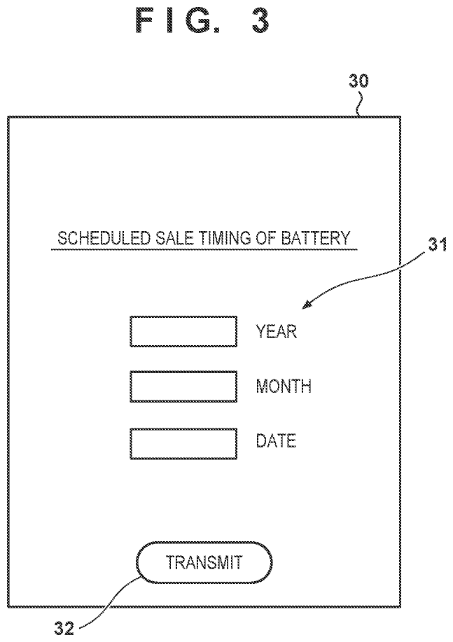

In S101, the processing unit 11 determines whether timing information indicating the scheduled sale timing (predetermined time) of the battery B has been received from the charge control device 20 (user). For example, in a case where there is an instruction input from the user or the like, the charge control device 20 displays an input screen 30 of the scheduled sale timing as illustrated in FIG. 3 on the display unit 24. An example of the input screen 30 includes an input field 31 of the scheduled sale timing and a send button 32. Then, in a case where the scheduled sale timing of the battery B is input in the input field 31 by the user and the send button 32 is touched (pressed) on the screen, the charge control device 20 transmits timing information indicating the scheduled sale timing to the server device 10 via the network NTW. As a result, the processing unit 11 of the server device 10 can determine whether the timing information has been received from the charge control device 20. In a case where the timing information has not been received, S101 is repeated, and in a case where the timing information has been received, the process proceeds to S102.

In S102, the processing unit 11 (acquisition unit 11a) acquires battery information from the charge control device 20 (user). The battery information may include information regarding a model/shape of the battery B, information regarding a location of the battery B (charge control device 20), information regarding an initial full charge capacity of the battery B, and the like in addition to the timing information received in S101. Next, in S103, the processing unit 11 (acquisition unit 11a) acquires rank information indicating the product rank set (selected) by the user as the reuse destination of the battery B from the charge control device 20 (user).

For example, the storage unit 12 (database) of the server device 10 stores information (hereinafter, it may be referred to as product information) indicating a correspondence relationship between various product types and the model/shape of the battery mounted on the product types. The processing unit 11 selects a plurality of product types on which the battery B can be mounted as a plurality of product ranks from the product information stored in the storage unit 12 based on the battery information (in particular, information regarding the model/shape of the battery B) acquired in S102. In addition, the storage unit 12 of the server device 10 stores data indicating transition (fluctuation) of a general battery price traded in the market in the past for each of various product types. The processing unit 11 acquires data indicating transition of the price of a general battery in the past several years from the storage unit 12 for each of the plurality of selected product ranks, and predicts the transaction price (market price) of the general battery at the scheduled sale timing on the basis of the data. Hereinafter, the predicted general battery transaction price may be referred to as a “predicted transaction price”.

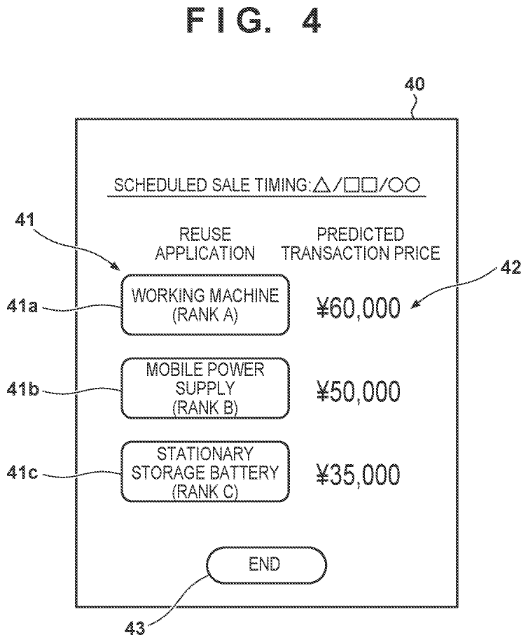

The processing unit 11 transmits data pieces of a plurality of product ranks and predicted transaction prices obtained through the above processing to the charge control device 20 via the network NTW. As illustrated in FIG. 4, the charge control device 20 that has received the data displays a screen for notifying (presenting) each product rank and the predicted transaction price on the display unit 24. A screen 40 illustrated in FIG. 4 is provided with a display 41 of a product rank (product type) on which the battery B can be mounted, a display 42 of a predicted transaction price, and an end button 43 for giving an end instruction of the management process. In FIG. 4, as the product rank, a working machine (rank A), a mobile power supply (rank B), and a stationary storage battery (rank C) are exemplified. The ranks A to C represent ranks of deterioration states (request states) required for a battery in a case where the battery is reused for each product type. In the case of the present embodiment, the rank A has a higher request state than the rank B (that is, the required deterioration state (deterioration degree) is small), and the rank B has a higher request state than the rank C.

In addition, on the screen 40 illustrated in FIG. 4, displays 41a to 41c of the respective product ranks are selection buttons, and the user can select a target product rank (target product rank) as a reuse destination of the battery B at the scheduled sale timing by touching (pressing) any one of the displays 41a to 41c on the screen. In a case where any one of the displays 41a to 41c of the product rank is touched (selected) on the screen by the user, the charge control device 20 transmits information regarding the target product rank selected by the user as rank information to the server device 10 via the network NTW. In this manner, the server device 10 can acquire the rank information.

In S104, the processing unit 11 (acquisition unit 11a) acquires the current deterioration state of the battery B. For example, the processing unit 11 transmits an instruction signal for detecting the deterioration state of the battery B to the charge control device 20. The charge control device 20 that has received the instruction signal detects the deterioration state of the battery B by the detection unit 25, and transmits the detection result (deterioration state information) to the server device 10. As a result, the processing unit 11 of the server device 10 can acquire the current deterioration state of the battery B. As described above, the deterioration state of the battery B includes the SOH of the battery B, but may further include the SOC.

In S105, the processing unit 11 (determination unit 11b) determines an item (restriction item) to restrict the function of the vehicle V so that the deterioration state of the battery B at the scheduled sale timing satisfies the request state of the target product rank based on the current deterioration state of the battery B acquired in S104. For example, the vehicle V has a plurality of types of functions, and the degradation rate of the battery B may change according to the execution of the various functions. Examples of the function of the vehicle V that can be the restricted target include rapid cooling and heating for rapidly cooling and heating the inside of the vehicle, an air conditioner for adjusting the humidity of the air inside the vehicle, and rapid acceleration of the vehicle V. Note that the information indicating the function of the vehicle V that can be the restricted target can be included in the battery information acquired in S102.

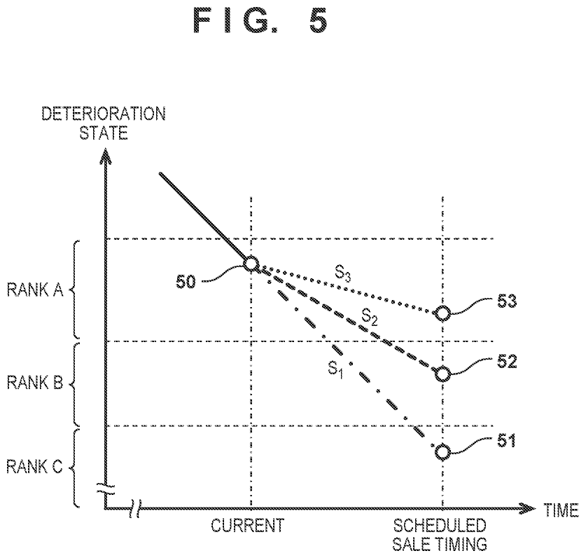

As an example, as illustrated in FIG. 5, the processing unit 11 sets a plurality of combinations of restriction items of the function of the vehicle V, and calculates degradation rates s₁ to s₃ of the battery B for each of the plurality of set combinations. Then, based on the current deterioration state 50 of the battery B acquired in S104, it is assumed that the battery B deteriorates at each of the degradation rates s₁ to s₃, and the deterioration states s₁ to s₃ of the battery B at the scheduled sale timing is estimated. As a result, the processing unit 11 can determine the combination of the restriction items of the function of the vehicle V so that the deterioration state of the battery B at the scheduled sale timing satisfies the request state of the target product rank. In the present embodiment, it is assumed that “rank B” is selected by the user as the target product rank, and “rapid cooling and heating restriction” and “rapid acceleration restriction” are determined by the processing unit 11 as the restriction items of the function of the vehicle V.

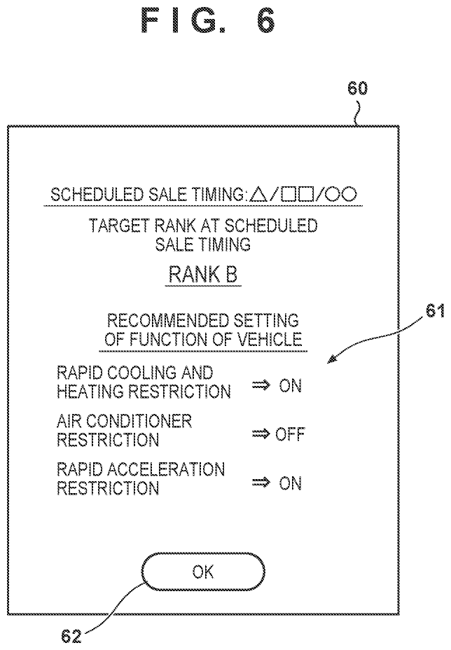

In S106, the processing unit 11 (notification unit 11c) notifies the charge control device 20 (user) of information (restriction item information) indicating the restriction item of the function of the vehicle V determined in S105. The charge control device 20 that has received the restriction item information displays a screen 60 including a display 61 of recommended settings (ON or OFF) for various functions of the vehicle V on the display unit 24 as illustrated in FIG. 6 based on the restriction item information. In the example illustrated in FIG. 6, the recommended setting of the rapid cooling and heating restriction and the rapid acceleration restriction determined as the restriction items is “ON,” and the recommended setting of the air conditioner restriction not determined as the restriction item is “OFF”. By displaying the restriction item information on the display unit 24 in this manner, the user can set restrictions in various functions of the vehicle V based on the display.

The screen 60 is provided with an OK button 62. In a case where the user touches (presses) the OK button 62 on the screen, a signal indicating that the user touches the OK button 62 is transmitted from the charge control device 20 to the server device 10 via the network NTW. As a result, the server device 10 (processing unit 11) can know (recognize) that the user has confirmed the notified function restriction information. Here, in the present embodiment, an example in which the user manually sets the restriction in various functions of the vehicle V based on the restriction item information displayed on the display unit 24 has been described, but the present invention is not limited thereto, and the charge control device 20 may automatically set the restriction based on the restriction item information received from the server device 10.

In S107, the processing unit 11 determines whether charging of the vehicle V (battery B) is started in the charge control device 20. For example, in a case where the charge control device 20 and the vehicle V (battery B) are electrically connected by a charging cable, a signal indicating the electrical connection is transmitted from the charge control device 20 to the server device 10 via the network NTW. The server device 10 (processing unit 11) can determine that the charging of the vehicle V (battery B) is started by receiving the signal. In a case where it is determined that charging has been started, the processing returns to S104, and the processing unit 11 causes the detection unit 25 of the charge control device 20 to detect the deterioration state of the battery B, updates the restriction item information based on the detection result, and notifies the charge control device 20 (user) of the updated restriction item information. As described above, in the management system 100 of the present embodiment, every time when the deterioration state of the battery B is detected by the detection unit 25 of the charge control device 20, the restriction item information is updated and notified to the user. As a result, the processing unit 11 (management unit 11d) of the server device 10 can sequentially manage the deterioration state of the battery B of the vehicle V.

Here, the processing unit 11 (management unit 11d) preferably manages the deterioration information of the battery B detected by the detection unit 25 in association with the battery information (in particular, information regarding the location of the battery B) acquired in S102. As a result, the processing unit 11 can know what deterioration state the battery having and where the battery is, and can efficiently manage the reusable battery (reusable battery). In the case of the present embodiment, since the flowchart of the management processing illustrated in FIG. 2 is performed for each of the plurality of batteries B, the processing unit 11 (management unit 11d) can manage information indicating the location and the deterioration state of each of the plurality of batteries.

On the other hand, in a case where it is determined in S107 that charging is not started, the processing proceeds to S108, and the processing unit 11 determines whether the scheduled sale timing has come (has arrived). In a case where the scheduled sale timing has not arrived yet, the processing returns to S107, and in a case where the scheduled sale timing has arrived, the processing proceeds to S109. In S109, the processing unit 11 (notification unit 11c) notifies the charge control device 20 (user) that the scheduled sale timing has come. For example, the processing unit 11 transmits a signal indicating that the scheduled sale timing has come to the charge control device 20. The charge control device 20 that has received the signal displays a comment such as “the scheduled sale timing has come” on the display unit 24.

As described above, in the management system 100 of the present embodiment, the server device 10 notifies the user (charge control device 20) of the restriction item information indicating the item for restricting the function of the vehicle V based on the target product rank set (selected) by the user such that the deterioration state of the battery B at the scheduled sale timing satisfies the request state of the target product rank. As a result, the user can set restrictions in various functions of the vehicle V based on the notified restriction item information so that the deterioration of the battery B is reduced toward the request state of the target product rank. In addition, the management system 100 according to the present embodiment periodically detects the deterioration state of the battery B and manages (stores) the detection result together with information regarding the location of the battery B. As a result, the management system 100 (server device 10) can know what deterioration state the battery having and where the battery is, and can efficiently manage the reusable battery (reusable battery).

### Other Embodiments

In the first embodiment, an example in which the detection unit 25 detects the deterioration state of the battery B every time when the charging of the battery B is started has been described. However, the present invention is not limited to the start of charging of the battery B, and the detection unit 25 may detect the deterioration state of the battery B periodically (for example, every month, every week, or the like). As a result, the management system 100 (server device 10) can periodically update and know the deterioration state of the battery B.

Further, in the first embodiment, the predetermined time for reusing the battery B is set as the scheduled sale timing set by the user, but the present invention is not limited thereto, and the predetermined time can be arbitrarily set. For example, the predetermined time may be after the elapse of a preset period from the purchase date of the battery B (vehicle V) (for example, after 5 years or 10 years). Note that the information regarding a purchase date of the battery B can be included in, for example, the battery information acquired in S102 of the flowchart illustrated in FIG. 2.

In the first embodiment, the example in which the server device 10 performs the management processing of managing the battery B has been described, but the management processing is not limited thereto, and the charge control device 20 may perform the management processing. In this case, the charge control device 20 (processing unit 21) may have the function of the server device 10, and the management program, various types of information items, and various types of data pieces may be stored in the storage unit 22.

(Summary of First Embodiment)

1. A management system of the above first embodiments is a management system (e.g. 100) for managing a battery (e.g. B) mounted on a vehicle (e.g. V), comprising:

an acquisition unit (e.g. 11a) configured to acquire rank information indicating a product rank set by a user as a reuse destination of the battery; and

a notification unit (e.g. 11c) configured to notify the user of restriction item information indicating an item for restricting a function of the vehicle such that a deterioration state of the battery at a predetermined time satisfies a request state of the product rank, based on the rank information acquired by the acquisition unit.

According to the present embodiment, the user sets restrictions in various functions of the vehicle V based on the notified restriction item information, so that the vehicle can be used such that deterioration of the battery is reduced toward the target product rank (target product rank) request state.

2. In the above first embodiments, the system further comprises:

a detection unit (e.g. 25) configured to detect a deterioration state of the battery; and

a determination unit (e.g. 11b) configured to determine an item for restricting a function of the vehicle such that a deterioration state of the battery at the predetermined time satisfies a request state of the product rank, based on a detection result of the detection unit,

wherein the notification unit is configured to notify the user of the restriction item information based on the item determined by the determination unit.

According to the present embodiment, it is possible to set an item for restricting the function of the vehicle so as to reduce the deterioration of the battery toward the request state of the target product rank.

3. In the above first embodiments,

each time when the deterioration state of the battery is detected by the detection unit, the notification unit is configured to update the restriction item information based on the detection result of the detection unit and notify the user of the updated restriction item information.

According to the present embodiment, the deterioration state of the battery of the vehicle can be sequentially managed, and the information (restriction item information) indicating the restriction item of the function of the vehicle according to the deterioration state can be sequentially provided to the user.

4. In the above embodiments,

the detection unit is configured to periodically detect a deterioration state of the battery.

According to the present embodiment, it is possible to periodically provide the user of the information (restriction item information) indicating the restriction item of the function of the vehicle according to the deterioration state of the battery of the vehicle.

5. In the above first embodiments,

the detection unit is configured to detect a deterioration state of the battery every time when charging of the battery is started.

According to the present embodiment, since the deterioration state of the battery can be periodically detected by using the start of charging of the battery as a trigger, it is possible to periodically provide the user with information (restriction item information) indicating the restriction item of the function of the vehicle according to the deterioration state of the battery of the vehicle.

6. In the above first embodiments,

the acquisition unit is configured to acquire information indicating a scheduled sale timing of the battery set by the user as the predetermined time.

According to the present embodiment, when the user schedules to sell the battery, the battery can be managed so that the deterioration state of the battery satisfies the request state of the product rank.

7. In the above first embodiments,

the acquisition unit is configured to acquire the rank information by presenting a plurality of product ranks (e.g. 41) to the user, and causing the user to select one of the plurality of product ranks as a reuse destination of the battery.

According to the present embodiment, it is possible to cause the user to use the vehicle to reduce deterioration of the battery by targeting the product rank selected by the user as the reuse destination of the battery.

8. In the above first embodiments,

the acquisition unit is configured to, in a case of causing the user to select one of the plurality of product ranks, present a predicted transaction price (e.g. 42) of each product rank in the predetermined time to the user together with the plurality of product ranks.

According to the present embodiment, it is possible to provide the user of a determination material when selecting the product rank as the reuse destination of the battery.

9. In the above first embodiments,

the system further comprises a management unit (e.g. 11d) configured to manage information indicating a location and a deterioration state for each of a plurality of batteries.

According to the present embodiment, it can know what deterioration state the battery having and where the battery is, and can efficiently manage the reusable battery (reusable battery).

### Second Embodiment

In recent years, it has been studied to reuse a battery (reusable battery) mounted on an electric vehicle or a hybrid vehicle that has been spreading worldwide. Japanese Patent Laid-Open No. 2014-20818 discloses a technique for determining a degree of deterioration of a secondary battery by using an open voltage value, an internal resistance value, and a full charge capacity value of the secondary battery. However, since deterioration states (hereinafter, referred to as “states of health (SOH)”) of reusable batteries vary depending on the use environments and applications so far, electrical characteristics of the reusable batteries vary among individual batteries. In addition, the reusable battery has deteriorated due to use so far, and it is unclear when the product life will end, and the user uses the reusable battery while feeling uneasy about when the product life will end.

An object of the present embodiment is to provide a technique capable of generating a model for predicting a future life of a battery based on a degree of deterioration of the battery specified from a use history of the battery and a required specification of a user, and selecting and presenting a battery that meets a required specification of the user based on the generated model.

(Battery Information Providing System)

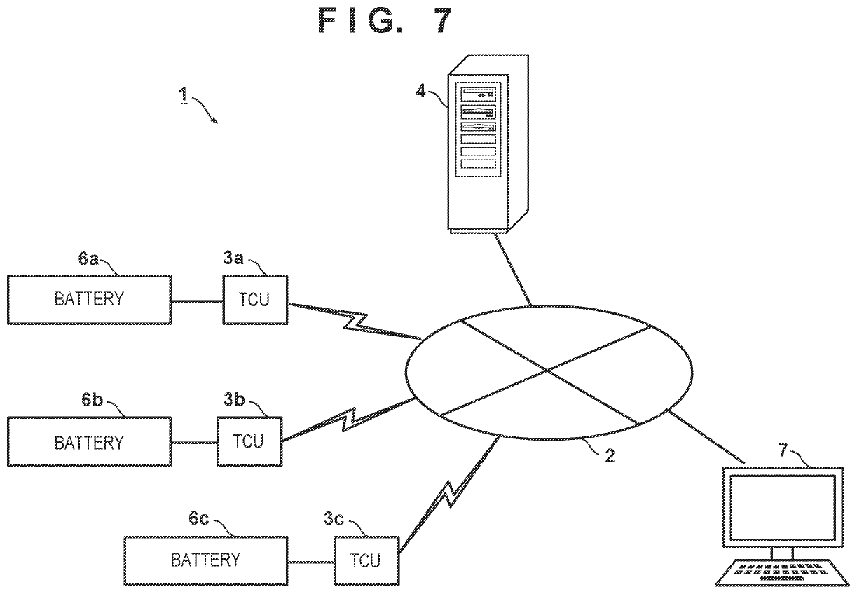

FIG. 7 is a block diagram illustrating a configuration of a representative battery information providing system 1 of the present embodiment. The battery information providing system 1 illustrated in FIG. 7 includes information communication devices 3a to 3c (telematics control units: TCUs), an information processing apparatus 7, and a server (information distribution device) 4 communicatively connected via a network 2.

The information communication devices 3a to 3c (TCUs) can perform signal processing for performing communication with the server 4 via the network 2. The information communication devices 3a to 3c (TCUs) are connected to batteries 6a to 6c, and transmit information acquired from the batteries 6a to 6c to the server 4 via the network 2. The plurality of information communication devices 3a to 3c (TCUs) are provided, for example, in stationary power storage devices operated by solar power generation, wind power generation, or the like, working machines such as lawn mowers, cultivators, and snow blowers, disaster-response storage batteries, residential storage batteries, electric motorcycles such as electric scooters, electric vehicles, hybrid vehicles, and the like.

Here, the reusable battery refers to a rechargeable secondary battery used as a power storage device, which is not suitable for, for example, an electric motorcycle such as an electric scooter, an electric vehicle, a hybrid vehicle, or the like because its chargeable capacity is equal to or less than a predetermined amount, but is reusable for other applications, and for example, a lithium ion battery is a representative example.

The information processing apparatus 7 functions as an operation terminal of the user, and is, for example, an information processing apparatus in the form of a personal computer, a general-purpose computer, a tablet terminal, a smartphone, or the like. The information processing apparatus 7 is connected to the server 4 via the network 2, and can transmit information to the server 4, receive information transmitted from the server 4, and present the received information on the display unit. In the information processing apparatus 7, a battery presentation program is installed as an application program for controlling processing in the information processing apparatus. By executing the battery presentation program, the information processing apparatus 7 provides a display screen (user interface) for inputting required specification information to be transmitted to the server 4, and processes information received from the server 4.

Here, the required specification information of the user is information indicating the user's request regarding the selection of the battery, and includes, for example, information regarding the name of the reusable product to which the reusable battery is applied, the model of the product, and the application of the reuse.

(Configuration of Reusable Battery)

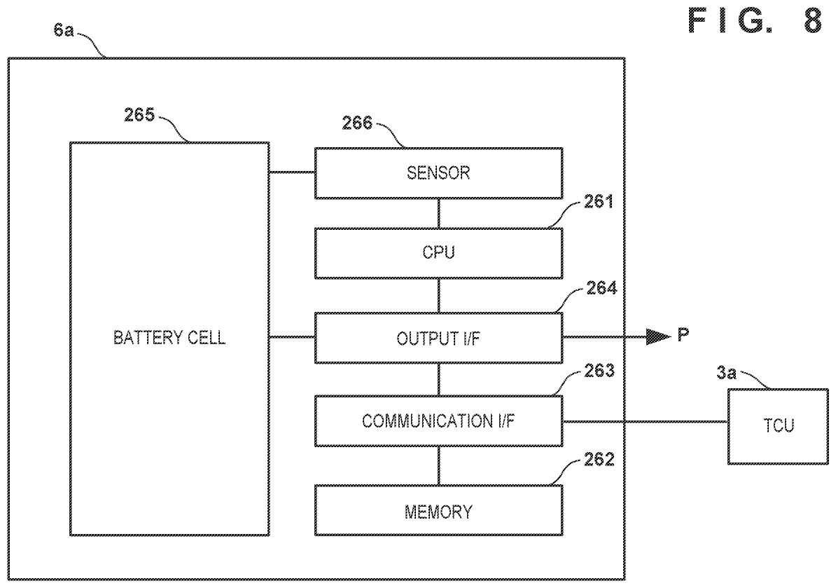

FIG. 8 is a block diagram illustrating a configuration of a battery. In the following description, the battery 6a will be described as a representative, but the same applies to the other batteries 6b and 6c. The reusable battery incorporates a plurality of cells including a lithium (Li) ion battery as a battery cell 265. As the reusable battery, a sodium ion secondary battery, a potassium ion secondary battery, or the like can be used as a cell of the battery cell 265 in addition to the lithium (Li) ion battery.

As illustrated in FIG. 8, a discharge voltage, an output current, a cell temperature, and the like of the battery cell 265 are monitored by a sensor 266. Power P supplied from the battery cell 265 is supplied via an output I/F 264 (output interface) having an output terminal. The CPU 261 stores various physical quantity data measured by the sensor 266 in a memory 262 (storage unit). The memory 262 includes a ROM storing a control program for operating the CPU 261 and a RAM used as a work area for executing the control program. In addition, the memory 262 stores model information of the battery 6a, specification information indicating rated performance of the battery, and the like. In addition, the memory 262 also stores use history information such as a maximum capacity, a charge/discharge cycle, a discharge voltage, an output density, a cell temperature, an SOH, and a state of charge (SOC) of the battery. The communication I/F 263 (communication interface) is an interface that connects the information communication device 3a (TCU) and the battery 6a, and the information communication device 3a (TCU) transmits information acquired from the memory 262 of the battery 6a to the server 4 via the communication I/F 263.

(Configuration of Server)

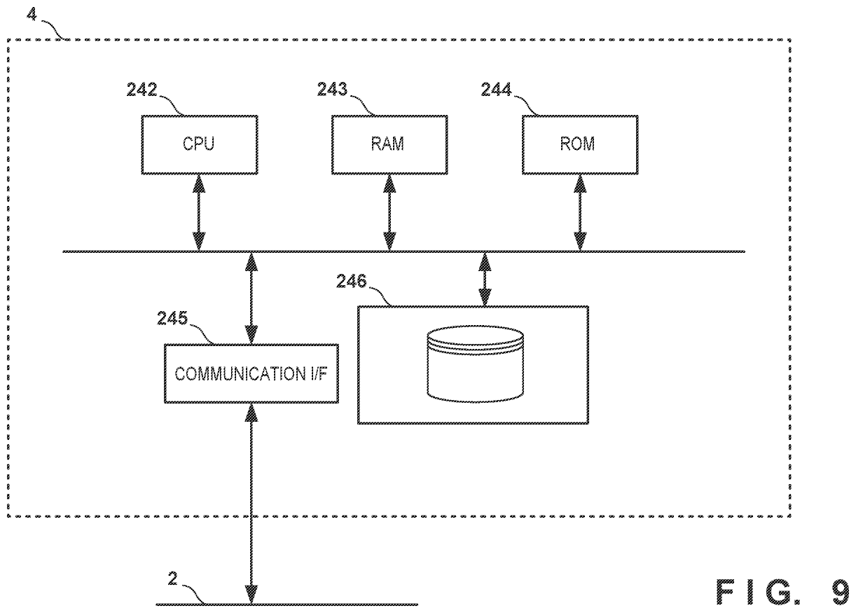

FIG. 9 is a block diagram illustrating a configuration of the server 4. As illustrated in FIG. 9, the server 4 includes a CPU 242 that executes and controls arithmetic processing in the server 4, a RAM 243, a ROM 244, a communication interface (I/F) 245, and a large-capacity storage device 246.

The server 4 can establish a communication link with the network 2 via a communication interface 245 and further communicate with the information communication devices 3a to 3c and the information processing apparatus 7 via the network 2. The server 4 acquires battery information including a battery use history via the communication interface 245 via the network 2.

In the storage device 246 that stores battery information, the CPU 242 generates a database in which batteries are classified on the basis of the use conditions and applications of the batteries specified from the battery information transmitted from the information communication devices 3a to 3c (TCUs).

The CPU 242 generates a model for predicting the future life of the battery based on the degree of deterioration of the battery specified from the battery information and the use condition in the use destination of the battery specified from the user's required specifications.

Here, the degree of deterioration of the battery indicates, for example, the SOH of the battery. The usage history of the reusable battery until the start of reuse is different for each battery, and the usage environment is different even after the start of reuse. Therefore, the degree of deterioration (deterioration characteristics) of the battery is also different from that included in the deterioration model on the premise of the new secondary battery.

The SOH representing the degradation characteristic can be formulated as a model function f0 {C01, C02, C03, . . . C0n} of various factors.

The CPU 242 generates a model function (first prediction model f1) based on the battery information obtained from each battery. The battery information is information reflecting information detected by the battery sensor 266, and by generating the first prediction model f1 obtained by reevaluating the model function f0 using the battery information, more accurate deterioration prediction can be performed.

Based on the battery information, the CPU 242 generates the first prediction model f1 that predicts the degree of deterioration of the battery based on the past use history of the battery.

f1={C01×k1,C02×k2,C03×k3, . . . C0n×kn}

Here, the parameter (coefficient ki) is a parameter corresponding to the information detected by the sensor 266, and indicates the degree of characteristic change regarding each parameter (COi) of the battery. The CPU 242 generates the first prediction model f1 that predicts the degree of deterioration of the battery based on the plurality of parameters (coefficients ki) acquired from the battery information.

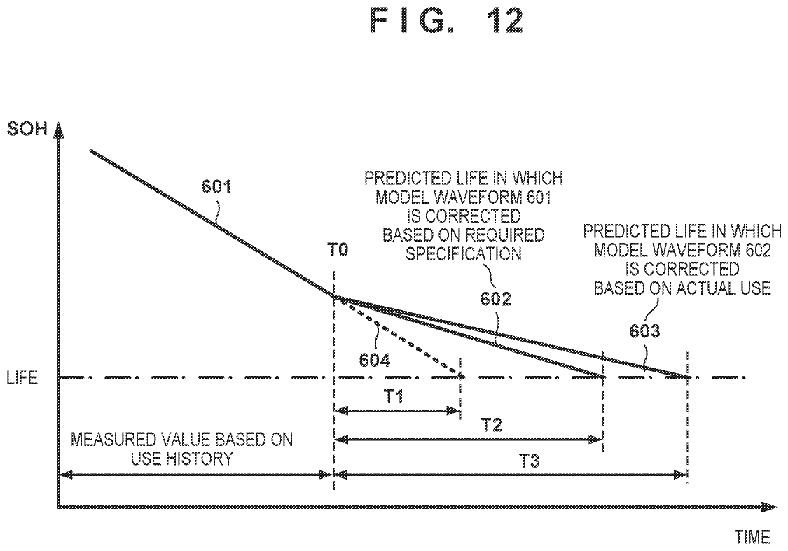

FIG. 12 is a diagram schematically describing a model for predicting a future life of a battery generated by the CPU 242, in which a horizontal axis indicates time and a vertical axis indicates SOH as a degree of deterioration (deterioration characteristics) of the battery. A model waveform 601 indicates the first prediction model f1. A portion indicated by a broken line 604 indicates a predicted value in a case where the battery is used under the same condition as the past use history, and indicates that the battery can be used for T1 hours (period) until the life reaches the end.

In addition, the CPU 242 generates a model (second prediction model) that predicts the life when the battery is used under the use condition at the use destination (reuse destination) of the battery specified from the user's required specifications. The use condition of the reuse destination is different from the use condition in the past use history, and is different from the first prediction model f1 indicated by the model waveform 601.

The CPU 242 generates a second prediction model f2 obtained by correcting a change in the degree of deterioration in a case where the first prediction model (model waveform 601) is used under the use condition as a model for predicting the life of the battery in the reuse destination of the battery.

f2={C01×m1,C02×m2,C03×m3, . . . C0n×mn}

Here, the parameter (coefficient mi) is a parameter set based on a use condition in a use destination (reuse destination) of the battery, and the parameter (coefficient mi) is set by the required specification information input from the information processing apparatus 7 by the user. The CPU 242 specifies a request for a desired battery model or a request for a model of a reusable product based on the required specification information of the user, and sets a parameter (coefficient mi) in a case where the battery is used at the rated performance in the reuse destination.

In FIG. 12, a model waveform 602 indicates the second prediction model f2. In a case where the battery is used in the second prediction model of the model waveform 602, it is indicated that the battery can be used for T2 hours (period) from a reuse start time T0 as a reference until the life reaches the end.

The CPU 242 of the server 4 selects a battery that meets the required specifications from the database of the storage device 246 based on the model for predicting the life, and presents the battery to the user. The information on the battery selected by the server 4 is transmitted to the information processing apparatus 7 via the network 2 and presented on the display unit 276 of the information processing apparatus 7. At this time, the CPU 242 estimates and presents the estimated remaining life (T2 in FIG. 12) of the selected battery based on a model for predicting the life.

By generating a model for predicting the life of the battery in consideration of the use conditions at the use destination (reuse destination) of the battery, the life of the battery can be obtained more accurately in the required specifications of the user, and can be presented to the user.

In addition, the CPU 242 generates a third prediction model f3 in which a change in the degree of deterioration in a case where the second prediction model is actually used at the use destination of the battery is corrected.

f3={C01×n1,C02×n2,C03×n3, . . . C0n×nn}

Here, the parameter (coefficient ni) is a parameter corresponding to the information detected by the sensor 266 when the battery is used in the reuse destination, and indicates the degree of characteristic change regarding each parameter (COi) of the battery. The CPU 242 generates the third prediction model f3 that predicts the degree of deterioration of the battery based on the plurality of parameters (coefficients ni) acquired from the battery information by sequential communication.

In FIG. 12, a model waveform 603 indicates the third prediction model f3. In a case where the battery is used in the third prediction model of the model waveform 603, it is indicated that the battery can be used for T3 hours (period) from a reuse start time T0 as a reference until the life reaches the end.

The CPU 242 of the server 4 estimates and presents the estimated remaining life of the selected battery based on the generated third prediction model. The information represented by the server 4 is transmitted to the information processing apparatus 7 via the network 2 and presented on the display unit 276 of the information processing apparatus 7.

By generating a model for predicting the life of the battery in consideration of the actual use history in the use destination (reuse destination) of the battery, the life of the battery can be obtained more accurately and presented to the user.

The CPU 242 presents a change in the estimated remaining life in actual use of the battery at the use destination based on a comparison between the estimated remaining life (T2 in FIG. 12) based on the model (second prediction model) for predicting the life generated in step S530 and the estimated remaining life (T3 in FIG. 12) estimated based on the third prediction model generated in step S560.

In a case where the actual use of the battery in the reusable product is the use with less load as compared with the rated performance on which the second prediction model is generated, the estimated remaining life (T3 in FIG. 12) is extended as compared with the estimated remaining life (T2 in FIG. 12) based on the second prediction model.

On the other hand, in a case where the actual use of the battery is the use of a high load as compared with the rated performance, the estimated remaining life (T3 in FIG. 12) is shortened as compared with the estimated remaining life (T2 in FIG. 12) based on the second prediction model.

By presenting the change in the estimated remaining life, the user can specifically identify how much more the battery can be used until the currently used battery (reusable battery) reaches its end of life. By presenting the user with a sequential change in the estimated remaining life, the user can review a usage status and improve the way of using to extend the life.

(Configuration of Information Processing Apparatus)

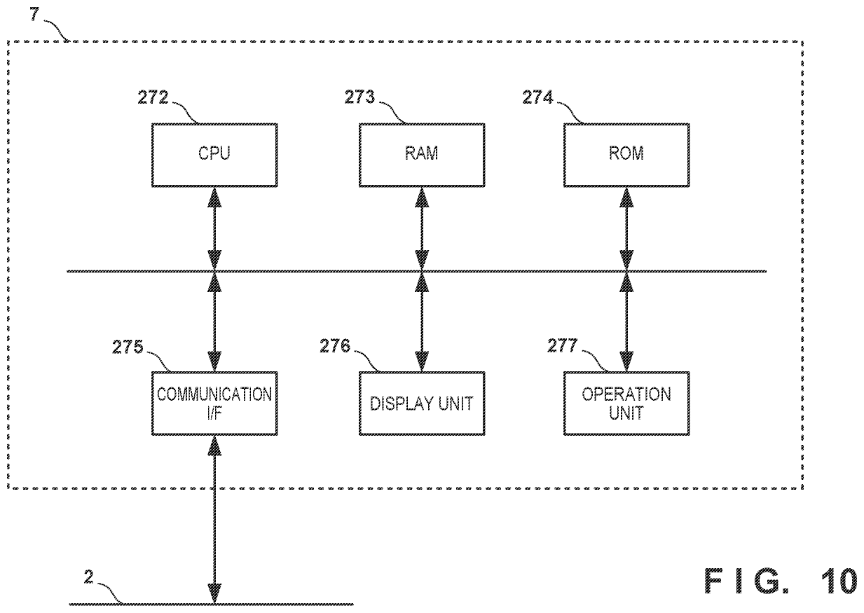

Next, a configuration of an information processing apparatus that functions as a user's operation terminal will be described. FIG. 10 is a diagram illustrating a configuration of an information processing apparatus 7 in a personal computer (PC) format. As illustrated in FIG. 10, the information processing apparatus 7 includes a CPU 272 that executes and controls arithmetic processing in the information processing apparatus 7, a RAM 273, a ROM 274, a communication interface (I/F) 275, a display unit 276, and an operation unit 277 for operating the information processing apparatus 7.

The operation unit 277 includes an information input unit such as a touch panel and a keyboard, and the user can input required specification information from the operation unit 277. When the battery presentation program installed in the ROM 274 is executed under the control of the CPU 272, the program is expanded in the RAM 273, and a display screen (user interface) for inputting required specification information is displayed on the display unit 276. The user inputs required specification information (for example, the name of the reusable product, the model of the product, the application of the reuse, and the like) of the user from the operation unit 277 while viewing the display screen of the display unit 276. When the input of the required specification information by the user is completed, the information processing apparatus 7 establishes communication with the server 4 via the network 2.

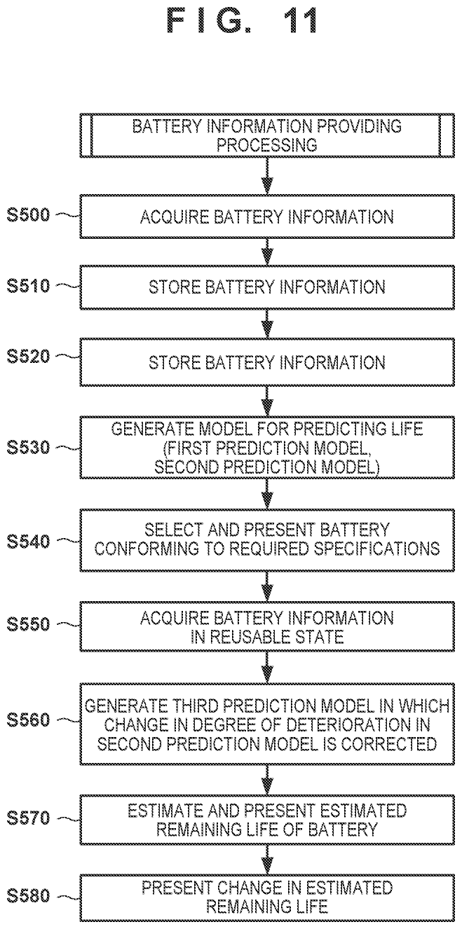

Next, a flow of processing executed by the battery information providing system 1 having the above configuration will be described. FIG. 11 is a diagram for illustrating a flow of processing in the battery information providing system.

In step S500, the CPU 242 of the server 4 communicates with the information communication devices 3a to 3c via the network 2, and acquires battery information including a battery use history via the communication interface 245.

In step S510, the CPU 242 stores the battery information acquired via the communication interface 245 in the database of the storage device 246.

In step S520, the CPU 242 communicates with the information processing apparatus 7 via the network 2, and acquires the required specification information of the user via the communication interface 245.

In step S530, the CPU 242 generates a model for predicting the future life of the battery based on the degree of deterioration of the battery specified from the battery information and the use condition in the use destination of the battery specified from the user's required specification information. Here, the model for predicting the future life of the battery is a model reflecting the use condition in the reusable product, and corresponds to the model waveform 602 (second prediction model f2) illustrated in FIG. 12. In this step, the model waveform 601 (first prediction model f1) is generated as the reference model, and the generated model waveform 601 (first prediction model f1) is corrected by the model waveform 602 (second prediction model f2).

In step S540, the CPU 242 of the server selects a battery conforming to the required specifications from the database of the storage device 246 based on the model generated in step S530, and presents the battery to the user. The CPU 242 presents the estimated remaining life of the battery based on the second prediction model (T2 in FIG. 12). The selected information on the battery is transmitted to the information processing apparatus 7 via the network 2 and presented on the display unit 276 of the information processing apparatus 7.

In step S550, the CPU 242 of the server 4 acquires battery information in the reusable state. The CPU 242 communicates with the information communication devices 3a to 3c via the network 2, and acquires battery information including a use history of a battery in a state of being used in a reusable product (reusable state) via the communication interface 245.

In step S560, the CPU 242 generates a third prediction model in which a change in the degree of deterioration in a case where the second prediction model is actually used at the use destination of the battery is corrected.

In step S570, the CPU 242 presents the estimated remaining life of the battery based on the third prediction model (T3 in FIG. 12). The CPU 242 estimates and presents the estimated remaining life of the selected battery based on the generated third prediction model. The information regarding the estimated remaining life is transmitted to the information processing apparatus 7 via the network 2 and presented on the display unit 276 of the information processing apparatus 7.

In step S580, the CPU 242 presents the change in the estimated remaining life (T3-T2 in FIG. 12). The CPU 242 presents a change in the estimated remaining life in actual use of the battery at the use destination based on a comparison between the estimated remaining life (T2 in FIG. 12) based on the model (second prediction model) generated in step S530 and the estimated remaining life (T3 in FIG. 12) estimated based on the third prediction model generated in step S560 (T3-T2 in FIG. 12). The information on the change in the estimated remaining life is transmitted to the information processing apparatus 7 via the network 2 and presented on the display unit 276 of the information processing apparatus 7.

The communication interface 245 of the server 4 acquires life end information indicating that the battery reaches the end of life via the network 2.

In a case where the life end information in the actual use is shorter than a threshold life shorter than the estimated remaining life (T2) based on the second prediction model (602 in FIG. 12), the CPU 242 of the server 4 excludes the battery of the same type as the battery from the selection target in the database of the storage device 246. The threshold life is a time (period) shorter than the estimated remaining life (T2), and is, for example, T1 hours (period) in FIG. 12.

In a case where the battery reaches its end of life in the reusable state (for example, in a case where the service life is reached in a shorter time than T2 in FIG. 12), the information communication device (TCU) connected to the battery transmits life end information indicating that the battery reaches its end of life to the server 4 via the network 2 as battery information. In the server 4, in a case where the life end information in actual use is shorter than the threshold life shorter than the estimated remaining life (T2) based on the second prediction model (602 in FIG. 12), the batteries of the same type and the batteries of a similar type specified by the battery information are excluded from the selection target in the database of the storage device 246 based on the battery information (life end information) transmitted from the information communication device (TCU). As a result, it is possible to exclude the battery that has reached the life of the battery in a short time (short period) as compared with the estimated remaining life (T2) from the selection target.

(Summary of Second Embodiment)

The second embodiment discloses at least the following battery information providing system and battery information providing method.

Configuration 1. A battery information providing system of the above second embodiments comprises:

an acquisition unit (e.g. 245 of FIG. 9) configured to acquire, via a network, battery information including a use history of a battery;

a storage unit (e.g. 242, 246 of FIG. 9) configured to store the battery information;

a generation unit (e.g. 242 of FIG. 9) configured to generate a model for predicting a future life of the battery based on a degree of deterioration of the battery specified from the battery information and a use condition of the battery at a use destination specified from a required specification of a user; and

a presentation unit (e.g. 242 of FIG. 9, 276 of FIG. 10) configured to select a battery conforming to the required specification from the storage unit based on the model and present the battery to the user.

According to the battery information providing system of Configuration 1, it is possible to provide a technique capable of generating a model for predicting a future life of a battery based on a degree of deterioration of the battery specified from a use history of the battery and a required specification of a user, and selecting and presenting a battery that meets a required specification of the user based on the generated model. As a result, the user can know the expected time at which the product reaches the end of life, and can purchase and use the product with a sense of security.

Configuration 2. In the battery information providing system (e.g. 1) of the above second embodiments, the storage unit is configured to generate a database in which the batteries are classified, based on a use condition and an application of the batteries specified from the battery information.

According to the battery information providing system of Configuration 2, the acquired battery information is obtained by collecting various types of data pieces from various vehicles and devices over a long period of time, and it is possible to generate a database of so-called big data.

Configuration 3. In the battery information providing system (e.g. 1) of the above second embodiments, the generation unit (242) configured to:

generate, based on the battery information, a first prediction model (e.g. 601 of FIG. 12) for predicting a degree of deterioration of a battery based on a past use history of the battery and

generate, as the model for predicting the life, a second prediction model (e.g. 602 of FIG. 12) in which a change in the degree of deterioration in a case where the first prediction model is used under the use conditions is corrected.

Configuration 4. In the battery information providing system (e.g. 1) of the above second embodiments, the presentation unit (242, 276) is configured to estimate a remaining life (e.g. T2 of FIG. 12) of the selected battery based on the model generated by the generation unit (242), and present the estimated remaining life.

According to the battery information providing systems of Configuration 3 and Configuration 4, by generating a model for predicting the life of the battery in consideration of the use conditions at the use destination (reuse destination) of the battery, the life of the battery can be obtained more accurately in the required specifications of the user, and can be presented to the user. By using a highly accurate prediction model, it is possible to provide a battery having an appropriate life according to the product life of a reuse destination.

Configuration 5. In the battery information providing system (e.g. 1) of the above second embodiments, the generation unit (242) is configured to generate a third prediction model (e.g. 603 of FIG. 12) in which a change in the degree of deterioration in a case where the second prediction model is actually used at the use destination of the battery is corrected.

Configuration 6. In the battery information providing system (e.g. 1) of the above second embodiments, the presentation unit (242, 276) is configured to estimate a remaining life (e.g. T3 of FIG. 12) of the selected battery based on the third prediction model (603) generated by the generation unit, and present the estimated remaining life.

According to the battery information providing systems of Configuration 5 and Configuration 6, by generating a model for predicting the life of the battery in consideration of the actual use history at the use destination (reuse destination) of the battery, the life of the battery can be obtained more accurately, and can be presented to the user.

Configuration 7. In the battery information providing system (e.g. 1) of the above second embodiments, the presentation unit (242, 276) configured to present a change in the estimated remaining life in use of the battery at a use destination, based on a comparison between the estimated remaining life (e.g. T2 of FIG. 12) based on the model and the estimated remaining life (e.g. T3 of FIG. 12) estimated based on the third prediction model (603).

According to the battery information providing system of Configuration 7, by presenting the change in the estimated remaining life, the user can specifically identify how much more the battery can be used until the currently used battery (reusable battery) reaches its end of life. By presenting the user with a sequential change in the estimated remaining life, the user can review a usage status and improve the way of using to extend the life.

The secondary user of the collection and the waste can predict the collection time (for example, the end timing of T3 in FIG. 12) and the secondary availability time of the battery, and the production plan can be optimized even by reusing in a product group (for example, a lawn mower, a cultivator, a snow blower, or the like) whose demand is seasonal.

Configuration 8. In the battery information providing system (e.g. 1) of the above second embodiments, the acquisition unit is configured to acquire, via the network, life end information indicating that the battery has reached the end of life, and

the generation unit (242) is configured to, in a case where the life end information is shorter than a threshold life shorter than an estimated remaining life (T2) based on the second prediction model, exclude a battery of the same type as the battery from a selection target in the storage unit (246).

According to the battery information providing system of Configuration 8, it is possible to exclude the battery that has reached the life of the battery in a short time (short period) as compared with the threshold life shorter than the estimated remaining life (T2) from the selection target. As a result, it is possible to select and present a battery having a value of reuse by excluding a battery having a short actual life as compared with the threshold life shorter than the estimated remaining life predicted from the selection target.

Configuration 9. A battery information providing method of the above second embodiments is a battery information providing method in a battery information providing system, comprising:

acquiring, via a network, battery information including a use history of a battery (e.g. S500 of FIG. 11);

storing the battery information in a storage unit (e.g. S510 of FIG. 11);

generating a model for predicting a future life of the battery based on a degree of deterioration of the battery specified from the battery information and a use condition of the battery at a use destination specified from a required specification of a user (e.g. S530 of FIG. 11); and

selecting a battery conforming to the required specification from the storage unit based on the model and presenting the battery to the user (e.g. S540 of FIG. 11).

According to the battery information providing method of Configuration 9, it is possible to provide a technique capable of generating a model for predicting a future life of a battery based on a degree of deterioration of the battery specified from a use history of the battery and a required specification of a user, and selecting and presenting a battery that meets a required specification of the user based on the generated model. As a result, the user can know the expected time at which the product reaches the end of life, and can purchase and use the product with security.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A management system for managing a battery mounted on a vehicle, comprising:
an acquisition unit configured to acquire rank information indicating a product rank set by a user as a reuse destination of the battery; and
a notification unit configured to notify the user of restriction item information indicating an item for restricting a function of the vehicle such that a deterioration state of the battery at a predetermined time satisfies a request state of the product rank, based on the rank information acquired by the acquisition unit.

2. The management system according to claim 1, further comprising:
a detection unit configured to detect a deterioration state of the battery; and
a determination unit configured to determine an item for restricting a function of the vehicle such that a deterioration state of the battery at the predetermined time satisfies a request state of the product rank, based on a detection result of the detection unit,
wherein the notification unit is configured to notify the user of the restriction item information based on the item determined by the determination unit.

3. The management system according to claim 2, wherein each time when the deterioration state of the battery is detected by the detection unit, the notification unit is configured to update the restriction item information based on the detection result of the detection unit and notify the user of the updated restriction item information.

4. The management system according to claim 2, wherein the detection unit is configured to periodically detect a deterioration state of the battery.

5. The management system according to claim 2, wherein the detection unit is configured to detect a deterioration state of the battery every time when charging of the battery is started.

6. The management system according to claim 1, wherein the acquisition unit is configured to acquire information indicating a scheduled sale timing of the battery set by the user as the predetermined time.

7. The management system according to claim 1, wherein the acquisition unit is configured to acquire the rank information by presenting a plurality of product ranks to the user, and causing the user to select one of the plurality of product ranks as a reuse destination of the battery.

8. The management system according to claim 7, wherein the acquisition unit is configured to, in a case of causing the user to select one of the plurality of product ranks, present a predicted transaction price of each product rank in the predetermined time to the user together with the plurality of product ranks.

9. The management system according to claim 1, further comprising: a management unit configured to manage information indicating a location and a deterioration state for each of a plurality of batteries.

10. A non-transitory computer-readable storage medium storing a program for causing a computer to function as a management system according to claim 1.

11. A management method for managing a battery mounted on a vehicle, comprising:
acquiring rank information indicating a product rank set by a user as a reuse destination of the battery; and
notifying the user of restriction item information indicating an item for restricting a function of the vehicle such that a deterioration state of the battery at a predetermined time satisfies a request state of the product rank, based on the acquired rank information.

12. A server device for managing a battery mounted on a vehicle, comprising:
an acquisition unit configured to acquire rank information indicating a product rank set by a user as a reuse destination of the battery; and
a notification unit configured to notify the user of restriction item information indicating an item for restricting a function of the vehicle such that a deterioration state of the battery at a predetermined time satisfies a request state of the product rank, based on the rank information acquired by the acquisition unit.

13. A battery information providing system comprising:
an acquisition unit configured to acquire, via a network, battery information including a use history of a battery;
a storage unit configured to store the battery information;
a generation unit configured to generate a model for predicting a future life of the battery based on a degree of deterioration of the battery specified from the battery information and a use condition of the battery at a use destination specified from a required specification of a user; and
a presentation unit configured to select a battery conforming to the required specification from the storage unit based on the model and present the battery to the user.

14. The battery information providing system according to claim 13, wherein the storage unit is configured to generate a database in which the batteries are classified, based on a use condition and an application of the batteries specified from the battery information.

15. The battery information providing system according to claim 13, wherein the generation unit configured to:
generate, based on the battery information, a first prediction model for predicting a degree of deterioration of a battery based on a past use history of the battery and
generate, as the model for predicting the life, a second prediction model in which a change in the degree of deterioration in a case where the first prediction model is used under the use conditions is corrected.

16. The battery information providing system according to claim 13, wherein the presentation unit is configured to estimate a remaining life of the selected battery based on the model generated by the generation unit, and present the estimated remaining life.

17. The battery information providing system according to claim 15, wherein the generation unit is configured to generate a third prediction model in which a change in the degree of deterioration in a case where the second prediction model is actually used at the use destination of the battery is corrected.

18. The battery information providing system according to claim 17, wherein the presentation unit is configured to estimate a remaining life of the selected battery based on the third prediction model generated by the generation unit, and present the estimated remaining life.

19. The battery information providing system according to claim 18, wherein the presentation unit configured to present a change in the estimated remaining life in use of the battery at a use destination, based on a comparison between the estimated remaining life based on the model and the estimated remaining life estimated based on the third prediction model.

20. The battery information providing system according to claim 15, wherein
the acquisition unit is configured to acquire, via the network, life end information indicating that the battery has reached the end of life, and
the generation unit is configured to, in a case where the life end information is shorter than a threshold life shorter than an estimated remaining life based on the second prediction model, exclude a battery of the same type as the battery from a selection target in the storage unit.

21. A battery information providing method in a battery information providing system, comprising:
acquiring, via a network, battery information including a use history of a battery;
storing the battery information in a storage unit;
generating a model for predicting a future life of the battery based on a degree of deterioration of the battery specified from the battery information and a use condition of the battery at a use destination specified from a required specification of a user; and
selecting a battery conforming to the required specification from the storage unit based on the model and presenting the battery to the user.
